(19) United States
(12) Patent Application Publication
(10) Pub. No.: US 2025/0084351 A1
(43) Pub. Date: Mar. 13, 2025

(54) PROCESSING SOLUTION, METHOD FOR PROCESSING SUBSTRATE, AND METHOD FOR MANUFACTURING SEMICONDUCTOR SUBSTRATE

(71) Applicant: TOKYO OHKA KOGYO CO., LTD., Kanagawa (JP)

(72) Inventors: Jun IIOKA, Kanagawa (JP); Aaron GELL, Hillsboro, OR (US)

(21) Appl. No.: 18/828,149

(22) Filed: Sep. 9, 2024

Related U.S. Application Data
(60) Provisional application No. 63/581,858, filed on Sep. 11, 2023.

(51) Int. Cl. C11D 7/08; C11D 7/32; C11D 7/34; H01L 21/02

(52) U.S. Cl. CPC C11D 7/08; C11D 7/3281; C11D 7/34; H01L 21/02068

(57) ABSTRACT

There are provided a processing solution, including: an oxidizing agent (A), and hexafluorosilicic acid (B), in which a molar ratio of the content of the hexafluorosilicic acid (B) to the content of the oxidizing agent (A) is from 8 to 1900; a method for processing a substrate; and a method for manufacturing a semiconductor substrate.

### TECHNICAL FIELD

The present invention relates to a processing solution, a method for processing a substrate, and a method for manufacturing a semiconductor substrate.

### BACKGROUND ART

In a wiring forming step, for example, a substrate, a metal wiring layer, and an interlayer insulating film which is silicon-based or the like are laminated in this order; a hard mask layer (HM layer) is formed on the interlayer insulating film to form a laminate and the like; and the hard mask layer is etched to form a basic shape of a wiring pattern. As a material of the hard mask layer, for example, titanium or a titanium-based alloy such as titanium nitride (TiN), titanium oxide (TiOₓ (x represents a number.)), etc. is used. Thus, a protective film of a titanium-based metal such as titanium and a titanium-based alloy is used as a hard mask layer.

Next, the interlayer insulating film is dry etched using the HM layer as a mask layer to produce a wiring pattern such as a metal wiring, and the like.

Then, by processing an element (for example, substrate/metal wiring layer/interlayer insulating film/HM layer) after dry etching using a processing solution, the HM layer is removed, and an inorganic substance-containing residue derived from the HM layer or the metal wiring layer is cleaned away from the substrate.

As such a processing solution for removing a dry etching residue, a processing solution containing hydrogen fluoride, hydroxylamine, or the like as a main component is used. For example, Patent Document 1 discloses a glass substrate cleaning liquid containing (A) a hydrogen fluoride, (B) a hydrogen fluoride salt, (C) an alkylene polyamine polycarboxylic acid in which the total number of a carboxyl group and a hydroxy group is an odd number (where, the number of hydroxy group(s) may be 0), and (D) water.

### PATENT DOCUMENT

[Patent Document 1] Japanese Patent Application Laid-Open No. 2019-163362

### SUMMARY OF THE INVENTION

The present inventors conducted detailed studies on components commonly used in processing solutions, such as hydrogen fluoride, hydrogen peroxide, hydroxylamine, etc. As a result, the present inventors have found that processing solutions containing these as a main component have room for improvement in achieving both the removal of a protective film and suppression of damage to a pattern when a titanium-based metal (titanium or a titanium-based alloy) is used as a material of the protective film such as the HM layer, the mask layer, and the like mentioned above.

The present invention has been made in view of the above circumstances, and it is an object of the present invention to provide a processing solution that can efficiently remove a protective film containing a titanium atom and is excellent in suppression of damage to a pattern, a method for processing a substrate using the same, and a method for manufacturing a semiconductor substrate.

As a result of intensive studies to achieve the above object, the present inventors have found a processing solution that includes: an oxidizing agent (A), and hexafluorosilicic acid (B), in which a molar ratio of a Si atom of the hexafluorosilicic acid (B) to the content of the oxidizing agent (A) is from 8 to 1900, and have thus completed the present invention. That is, the present invention is as follows:

<1> A processing solution, including: an oxidizing agent (A), and hexafluorosilicic acid (B), in which a molar ratio of a Si atom of the hexafluorosilicic acid (B) to the content of the oxidizing agent (A) is from 8 to 1900.
<2> The processing solution according to <1>, further including: water as a solvent.
<3> The processing solution according to <2>, in which a pH value of the processing solution is 3.5 or less.
<4> The processing solution according to <1>, in which the oxidizing agent includes at least one selected from the group consisting of iodic acid, and periodic acid.
<5> The processing solution according to <1>, in which the oxidizing agent includes iodic acid.
<6> The processing solution according to <1>, in which a content of the oxidizing agent is from 1 to 600 ppm by mass.
<7> The processing solution according to <1>, further including: an anticorrosive agent.
<8> The processing solution according to <7>, in which the anticorrosive agent includes two or more kinds of anticorrosive agent.
<9> The processing solution according to <7>, in which the anticorrosive agent includes at least one selected from the group consisting of: an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, a phenanthroline ring-containing compound, a benzothioazole ring-containing compound, an oxindole, and tetraalkyl indolium iodide.
<10> The processing solution according to <1>, in which the processing solution is for a substrate that includes a protective film containing a titanium atom, and an insulating layer containing a silicon atom.
<11> The processing solution according to <10>, in which the substrate further includes a metal layer containing a metal atom other than a titanium atom and a silicon atom.
<12> A method for processing a substrate, including: etching a substrate including a protective film containing a titanium atom, and a metal layer containing a silicon atom; and processing the etched substrate using the processing solution according to <1>.
<13> A method for manufacturing a semiconductor substrate, including: etching a substrate including a protective film containing a titanium atom, and a metal layer containing a silicon atom; and processing the etched substrate using the processing solution according to <1>.

The present invention can provide a processing solution that can efficiently remove a protective film containing a titanium atom and is excellent in suppression of damage to a pattern, a method for processing a substrate using the same, and a method for manufacturing a semiconductor substrate.

### BRIEF DESCRIPTION OF THE DRAWINGS

FIG. 1 is a cross-sectional view showing an exemplary element to be processed after dry etching.

### DETAILED DESCRIPTION OF THE INVENTION

Hereinafter, an embodiment for carrying out the present invention (hereinafter simply referred to as “the present embodiment”) will be described in detail. The present embodiment below is an example for explaining the present invention, and it is not intended to limit the present invention to the following description. The present invention may be implemented with any appropriate modification within the scope of its gist.

In the drawings, the same elements are denoted by the same reference signs, and duplicate description will be omitted. In addition, the positional relationships such as top, bottom, left, and right are based on those illustrated in the drawings unless otherwise specified. Further, the dimensional ratios in the drawings are not limited to the illustrated ratios.

### <<First Aspect of Processing Solution>>

A first aspect of a processing solution according to the present embodiment is a processing solution, including: an oxidizing agent (A), and hexafluorosilicic acid (B), in which a molar ratio of a Si atom of the hexafluorosilicic acid (B) to the content of the oxidizing agent (A) is from 8 to 1900. A processing solution that satisfies these conditions can efficiently remove a protective film containing a titanium atom and is excellent in suppression of damage to a pattern. Examples of the protective film may include a hard mask layer, a mask layer, and the like.

Conventionally, hydrogen fluoride, etc. have been commonly used as a main component of an etchant of a processing solution used in the manufacture of a semiconductor from the viewpoint of ensuring etching performance, etc. However, the present inventors focused on a problem that it was difficult for a processing solution using hydrogen fluoride, etc. as a main component to achieve both etching performance and suppression of damage to a pattern (for example, anticorrosion properties, etc.) when a titanium-based metal is used in a protective film. Moreover, the present inventors changed their perspective and focused on hexafluorosilicic acid, which is milder than hydrogen fluoride, etc. As a result of intensive studies base on this, the present inventors have found that when the molar ratio of a Si atom of hexafluorosilicic acid to the content of an oxidizing agent is set to a specific ratio, it is possible to achieve both the above-mentioned etching performance and suppression of damage at high levels despite using hexafluorosilicic acid, which is milder. The present invention has thus been completed.

Furthermore, as will be described below, even if the processing solution according to the present embodiment contains (is combined with) an anticorrosive agent in one aspect, it maintains the effects of the removability of a protective film and suppression of damage to a pattern while it can also impart anticorrosion properties of the anticorrosive agent. This can be expected to widen the range of choice of metal kinds used in a pattern such as a metal wiring, etc.

The titanium-based metal used in a protective film refers to titanium and a titanium-based alloy, as described above. The titanium-based alloy refers to a form in which titanium, which is a metal, is bonded with a metal element other than titanium or a non-metal element. Although details will be described later, examples of the titanium-based alloy may include titanium nitride (TiN), titanium oxide (TiOₓ (x represents a number.), titanium oxynitride (TiON), titanium oxyfluoride (TiOF), and the like.

Examples of a pattern suitable for use of the processing solution according to the present embodiment may include a functional layer containing an atom of a metal (for example, metal wiring, metal layer, insulating layer, interlayer insulating film layer, and the like) and the like.

Examples of the metal may include at least one selected from the group consisting of metals such as molybdenum (Mo), tungsten (W), ruthenium (Ru), gold (Au), silver (Ag), copper (Cu), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc.; a metal oxide, a metal nitride, a metal chloride, a metal fluoride, etc. thereof; and the like. Examples of an inorganic substance other than metals may include silicon (Si), an oxide thereof (Unless otherwise specified, x represents a number.), a nitride (SiNₓ), a chloride (SiClₓ), a fluoride (SiFₓ), and the like.

Examples of the metal oxide may include a metal oxide of the metal atoms described above. Specific examples of the metal oxide may include, but are not limited to, TaOₓ, CuOₓ, CoOₓ, RuOₓ, AlOₓ, WOₓ, MoOₓ, AuOₓ, AgOₓ, FeOₓ, NiOₓ, and the like (Unless otherwise specified, x represents a number.).

Examples of the metal nitride may include a metal nitride of the metal atoms described above. Specific examples of the metal nitride may include, but are not limited to, TaNₓ, CuNₓ, CoNₓ, RuNₓ, AlNₓ, WNₓ, MoNₓ, AuNₓ, AgNₓ, FeNₓ, NiNₓ, and the like.

Examples of the metal chloride may include a metal chloride of the metal atoms described above. Specific examples of the metal chloride may include, but are not limited to, TaClₓ, CuClₓ, CoClₓ, RuClₓ, AlClₓ, WClₓ, MoClₓ, AuClₓ, AgClₓ, FeClₓ, NiClₓ, and the like.

Examples of the metal fluoride may include a metal fluoride of the metal atoms described above. Specific examples of the metal fluoride may include, but are not limited to, TaFₓ, CuFₓ, CoFₓ, RuFₓ, AlFₓ, WFₓ, MoFₓ, AuFₓ, AgFₓ, FeFₓ, NiFₓ, and the like.

A substrate suitable for use of the processing solution according to the present embodiment is preferably a substrate including a protective film containing a titanium atom and a functional layer containing at least one selected from the group consisting of a silicon atom, a tungsten atom, and a molybdenum atom; more preferably a substrate including a protective film containing a titanium atom and a functional layer containing a silicon atom; even more preferably a substrate including a protective film containing a titanium atom, a first functional layer containing a silicon atom, and a second functional layer containing at least one selected from the group consisting of a tungsten atom, a molybdenum atom, and a ruthenium atom; and even more preferably a substrate including a protective film containing a titanium atom, a first functional layer containing a silicon atom, a second functional layer containing a tungsten atom, and a third functional layer containing a molybdenum atom.

Specific examples of the functional layer may include those mentioned above. For example, suitable examples of the functional layer containing a silicon atom may include an insulating layer, an interlayer insulating film layer, etc. For example, suitable examples of the functional layer containing a tungsten atom and the functional layer containing a molybdenum atom may include a metal wiring, a metal layer, and the like.

The processing solution according to the present embodiment can be suitably used as a processing solution for removing an etching residue containing an inorganic substance. In particular, it can be suitably used as a processing solution for cleaning a semiconductor. The inorganic substance referred to here may include a metal, a metal oxide, a metal nitride, a metal chloride, a metal fluoride, etc., which constitute a protective film, a pattern, etc. That is, the processing solution according to the present embodiment can also efficiently remove an etching residue derived from such inorganic substances.

Therefore, the processing solution according to the present embodiment is expected to efficiently remove an inorganic-containing residue including one selected from the group consisting of below-described metals, and a metal oxide, a metal nitride, a metal chloride, and a metal fluoride thereof (However, the mechanism and effect according to the present embodiment are not limited thereto.).

The processing solution according to the present embodiment can efficiently remove a titanium-based metal protective film, and can remove the etching residue described above while suppressing damage to a fine pattern. From this viewpoint, the processing solution according to the present embodiment is suitable for removing an etching residue, and in particular it is more suitable for removing a dry etching residue. Usually, from the viewpoint of improving the yield of a semiconductor and preventing deterioration of electrical characteristics thereof, a dry etching residue is removed before the next step. For example, the processing solution according to the present embodiment is suitable for cleaning a semiconductor substrate after dry etching is performed in a wiring process. In particular, a titanium-based metal residue adhered on a semiconductor substrate after dry etching is a residue that has high wet resistance and is difficult to be removed by cleaning processing. The processing solution according to the present embodiment can also efficiently clean such a residue.

Furthermore, a pH value of the processing solution according to the present embodiment is preferably 3.5 or less. The upper limit of the pH value is more preferably 3.0 or less, even more preferably 2.8 or less, and still even more preferably 2.0 or less. The lower limit of the pH value is preferably 0.1 or more, more preferably 0.5 or more, even more preferably 0.8 or more, still even more preferably 1.3 or more, and further more preferably 1.5 or more. By setting the pH value of the processing solution to the above range, it is possible to achieve both the removal of a titanium-based metal protective film and suppression of damage to a pattern at higher levels. Furthermore, an effect can be expected that damage to many kinds of metals is suppressed when used in a pattern. From the viewpoint of obtaining such advantages, the pH is preferably 0.1 or more and 3.5 or less. The pH value refers to a value of the processing solution at normal pressure (1 atm) and 22° C. The pH value can be measured, for example, by a method described in Examples below.

### (Oxidizing Agent (A))

The processing solution according to the present embodiment contains an oxidizing agent (A). Thereby, a metal surface of a protective film can be oxidized, so that the protective film can be etched. Specific examples of the oxidizing agent may include halogen oxidizing agents (hypochlorous acid, chlorous acid, chloric acid, perchloric acid, hypobromous acid, bromous acid, bromic acid, perbromic acid, hypoiodous acid, iodite acid, iodic acid, periodic acid, and the like), boric acid (H₃BO₃, B(OH)₃), silicic acid, nitrous acid (HNO₂), nitric acid, sulfuric acid, sulfurous acid, and the like. The processing solution according to the present embodiment may contain a salt thereof as the oxidizing agent (for example, a sodium salt, a potassium salt, a calcium salt, a barium salt, an ammonium salt, a tetraalkylammonium salt, etc.).

Examples of the halogen oxidizing agents may include hypochlorous acid, chlorous acid, chloric acid, perchloric acid, hypobromous acid, bromous acid, bromic acid, perbromic acid, hypoiodous acid, iodite acid, iodic acid, periodic acid, and the like.

Among the above oxidizing agents, the oxidizing agent is preferably a halogen oxidizing agent; more preferably at least one selected from the group consisting of hypoiodous acid, iodite acid, iodic acid (HIO₃), periodic acid, and the like; and even more preferably at least one selected from the group consisting of iodic acid, and periodic acid; and still even more preferably iodic acid.

In the processing solution according to the present embodiment, one of the above-described oxidizing agents may be used alone, or two or more kinds thereof may be used in combination.

The concentration of the oxidizing agent in the processing solution according to the present embodiment is not particularly limited, but is preferably from 1 to 600 ppm by mass. The upper limit of the concentration of the oxidizing agent is more preferably 550 ppm by mass or less. The lower limit of the concentration of the oxidizing agent is more preferably 3 ppm by mass or more. The processing solution according to the present embodiment has a condition that the molar ratio of a Si atom of the hexafluorosilicic acid (B) to the content of the oxidizing agent (A), (Si/oxidizing agent, (B)/(A)), is a specific ratio. Together with the molar ratio condition, the content of the oxidizing agent within the above range can further improve the removal of a titanium-based metal protective film and suppression of damage to a pattern.

The processing solution according to the present embodiment is capable of removing a titanium-based metal protective film and suppressing damage to a pattern although it does not contain hydrogen fluoride (hydrofluoric acid in the case of an aqueous solution) as a main component. From this viewpoint, the content of hydrogen fluoride in the processing solution according to the present embodiment is preferably less than 0.1% by mass, more preferably less than 0.05% by mass, and even more preferably less than 0.001% by mass. Still even more preferably, the processing solution according to the present embodiment does not contain hydrogen fluoride.

From the similar viewpoint, the processing solution according to the present embodiment is capable of removing a titanium-based metal protective film and suppressing damage to a pattern although it does not contain hydrogen peroxide (a hydrogen peroxide solution in the case of an aqueous solution) as a main component. From this viewpoint, the content of hydrogen peroxide in the processing solution according to the present embodiment is preferably has less than 0.1% by mass, more preferably less than 0.05% by mass, and even more preferably less than 0.001% by mass. Still even more preferably, the processing solution according to the present embodiment does not contain hydrogen peroxide.

From the similar viewpoint, the content of hydroxylamine in the processing solution according to the present embodiment is preferably less than 0.1% by mass, more preferably less than 0.05% by mass, and even more preferably less than 0.001% by mass. Still even more preferably, the processing solution according to the present embodiment does not contain hydroxylamine.

From the viewpoints described above, more preferably the processing solution according to the present embodiment does not contain hydrogen fluoride, hydrogen peroxide, and hydroxylamine.

### (Hexafluorosilicic Acid (B))

The processing solution according to the present embodiment contains hexafluorosilicic acid (B). Thereby, a titanium-based metal protective film can be efficiently removed. Conventionally, a processing solution that removes a protective film by oxidation with an oxidizing agent and etching with hydrofluoric acid, and the like are widely used. Such a processing solution has a problem that a pattern containing a silicon atom (for example, a pattern of a silicon compound such as Si, SiOₓ, SiNₓ, SiClₓ, TEOS (tetraethoxysilane), etc.; x represents a number.) is also unintentionally etched, and balancing the removal of a protective film and suppression of damage to a pattern was insufficient. However, the processing solution according to the present embodiment contains the component (A) and the component (B) at a certain ratio and can thereby solve the problem.

The hexafluorosilicic acid (B) may be added as a hexafluorosilicate, or may be added as a hydrate, an aqueous solution, or the like. Specific examples of the hexafluorosilicate may include potassium hexafluorosilicate, sodium hexafluorosilicate, magnesium hexafluorosilicate, and the like.

The processing solution according to the present embodiment can obtain a predetermined effect even if it does not contain any component other than the component (A) and the component (B). Therefore, the processing solution according to the present embodiment may contain or may not contain any optional component other than the component (A) and the component (B), as necessary. Examples of the optional component may include a pH adjuster, a surfactant, an organic solvent, and the like. Even if these are not contained, a sufficient effect can be expected and hence these may not be contained. Further, the processing solution according to the present embodiment may contain a metal impurity described later within a range in which an mechanism or effect thereof can be obtained.

Among the above, the processing solution according to the present embodiment preferably contains an anticorrosive agent. Even when the processing solution according to the present embodiment contains an anticorrosive agent, it can maintain effects such as the removal of a protective film and suppression of damage to a pattern at practical levels. In addition to these advantages, an anticorrosion effect by the anticorrosive agent can also be imparted.

### (Anticorrosive Agent)

Specific examples of the anticorrosive agent may include, but are not particularly limited to, at least one selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, a phenanthroline ring-containing compound, a benzothioazole ring-containing compound, an oxindole, and tetraalkyl indolium iodide.

Among them, the triazole ring-containing compound and the tetrazole ring-containing compound are preferable. By using these compounds, for example, the anticorrosion properties of a pattern or a functional layer (for example, metal wiring, metal layer, insulating layer, interlayer insulating film layer, and the like) containing a tungsten atom or a molybdenum atom can be improved.

Specific examples of the imidazole ring-containing compound may include 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, 5-methylbenzimidazole, and the like. Among them, 5-methylbenzimidazole and the like are preferable.

Specific examples of the triazole ring-containing compound may include 1,2,4-triazole, 1,2,3-benzotriazole (BTA), 1,2,3-triazole, 3-amino-1H-1,2,4-triazole, 1-methyl-1H-benzotriazole, 5-methyl-1H-benzotriazole (5MBTA), 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, 3-aminotriazole, and the like. Among them, 1,2,3-benzotriazole, 1-methyl-1H-benzotriazole, 5-methyl-1H-benzotriazole, and the like are preferable.

Specific examples of the carbazole ring-containing compound may include 9H-carbazole, 4-hydroxycarbazole, 1-methyl-carbazole, 3-methyl-9H-carbazole, 9-methyl-1H-carbazole, 2-methoxycarbazole, 1-bromocarbazole, 2-bromocarbazole, 3-bromocarbazole, 4-bromocarbazole, 2-chlorocarbazole, 3-chlorocarbazole, 2-fluorocarbazole, 3-fluorocarbazole, 2-iodocarbazole, 3-iodocarbazole, 9-acetylcarbazole, 2,7-dibromocarbazole, 3,6-dibromocarbazole, 3,6-dichlorocarbazole, 2,3-benzcarbazole, 9-acetyl-3,6-diiodocarbazole, 2-bromo-7-methoxy-9H-carbazole, 3,6-dimethylcarbazole, 2,7-dimethylcarbazole, 3,6-diaminocarbazole, 3-amino-ethylcarbazole, 3,6-dimethoxy-9H-carbazole, 2,7-dimethoxy-9H-carbazole, 3,3′-bicarbazole, 7H-benzo[c]carbazole, and the like.

Specific examples of the pyridine ring-containing compound may include 1H-1,2,3-triazolo[4,5-b]pyridine, 1,2,4-triazolo[4,3-a]pyridin-3(2H)-one, 3H-1,2,3-triazolo[4,5-b]pyridin-3-ol, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, 4,4′-dinonyl-2,2′-bipyridyl, and the like. Among them, 1H-1,2,3-triazolo[4,5-b]pyridine is preferable.

Specific examples of the pyrimidine ring-containing compound may include pyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxypyrimidine, 2,4-diaminopyrimidine, 2-acetamidopyrimidine, 2-aminopyrimidine, 2-methyl-5,7-diphenyl-(1,2,4)triazolo(1,5-a)pyrimidine, 2-methylsulfanyl-5,7-diphenyl-(1,2,4)triazolo(1,5-a)pyrimidine, 2-methylsulfanyl-5,7-diphenyl-4,7-dihydro-(1,2,4)triazolo(1,5-a)pyrimidine, 4-aminopyrazolo[3,4-d]pyrimidine, and the like.

Examples of the tetrazole ring-containing compound may include 2,3,5-triphenyltetrazole, 2,3,5-triphenyltetrazolium chloride, 2,3,5-triphenyltetrazolium bromide, 1H-tetrazole, 5-amino-1H-tetrazole, 5-methyl-1H-tetrazole, 5-phenyl-1H-tetrazole, 1-(2-diaminoethyl)-5-mercaptotetrazole, and the like.

Examples of the pyrazole ring-containing compound may include 3,5-dimethylpyrazole, 3-amino-5-methylpyrazole, 4-methylpyrazole, 3-amino-5-hydroxypyrazole, 3-phenylpyrazole, indazole, 4-fluoroindazole, 5-nitroindazole, indazole-3-carboxylic acid, benzydamine hydrochloride, and the like. Among them, 3-phenylpyrazole, indazole, 4-fluoroindazole, 5-nitroindazole, indazole-3-carboxylic acid, benzydamine hydrochloride, and the like are preferable.

Specific examples of the purine ring-containing compound may include purine, and the like.

Specific examples of the phenanthroline ring-containing compound may include 1,10-phenanthroline, and the like.

Specific examples of the benzothioazole ring-containing compound may include benzothiazole, 2,5-dimethylbenzothiazole, 2,6-dimethylbenzothiazole, and the like. Among them, 2,5-dimethylbenzothiazole, 2,6-dimethylbenzothiazole, and the like are preferable.

Specific examples of tetraalkyl indolium iodide may include 1,2,3,3-tetramethyl-3H-indolium iodide, and the like.

The anticorrosive agent may also be a salt of the compounds described above. Specific examples of the salt may include, but are not particularly limited to, a sodium salt, a potassium salt, a chloride salt, an ammonium salt, an alkylammonium salt (for example, a tetramethylammonium salt, etc.), and the like. It may also be a hydrate of the above compounds.

The concentration of the anticorrosive agent in the processing solution according to the present embodiment is preferably from 0.0001 to 10% by mass. The upper limit of the concentration of the anticorrosive agent is more preferably 5% by mass or less, even more preferably 3% by mass or less, still even more preferably 2% by mass or less, and further more preferably 1% by mass or less. The lower limit of the concentration of the anticorrosive agent is more preferably 0.001% by mass or more, and even more preferably 0.01% by mass or more. When two or more kinds of anticorrosive agents are used in combination as the anticorrosive agent, the suitable concentration above refers to the total concentration of the anticorrosive agents. When the above-mentioned hydrate is used as the anticorrosive agent, it is preferable that the net content thereof excluding hydration water contained in the hydrate is within the above-described range.

The above-mentioned anticorrosive agents may be used alone or in combination of two or more. From the viewpoint of obtaining a further effect, the processing solution according to the present embodiment preferably contains two or more kinds of anticorrosive agents. The anticorrosive agent can be selected depending on the kind of a pattern or functional layer to be processed (for example, metal wiring, metal layer, insulating layer, interlayer insulating film layer, and the like). When the processing solution according to the present embodiment uses two or more kinds of anticorrosive agents, it is more preferable that it contains at least two or more selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound. These may be any of those mentioned above.

### (pH Adjuster)

The processing solution according to the present embodiment preferably contains a pH adjuster for the purpose of adjusting the pH to a desired level. As the pH adjuster, a known inorganic acid, organic acid, organic basic compound, inorganic basic compound and the like may be appropriately used within a range in which an effect of the present embodiment can be obtained.

Specific examples of the pH adjuster may include phosphoric acid, hydrochloric acid, sulfuric acid, methanesulfonic acid (MSA), citric acid, acetic acid, sodium dihydrogen phosphate, trisodium phosphate, sodium acetate, sodium hydroxide, sodium carbonate, sodium hydrogen carbonate, potassium hydroxide, potassium carbonate, potassium hydrogen carbonate, monoethanolamine, ammonia, ammonium carbonate, 2-amino-2-methyl-1-propanol, tripotassium citrate, diammonium hydrogen phosphate, and the like. Among them, methanesulfonic acid is preferable.

The pH adjuster may be used alone or in combination of two or more. Alternatively, the processing solution according to the present embodiment may not contain a pH adjuster.

### (Buffer)

The processing solution according to the present embodiment may contain a buffer. A buffer is a compound that has a mechanism of inhibiting a change in the pH of a processing solution. By containing a buffering agent, the processing solution can be efficiently controlled such that the pH of the processing solution is at a predetermined value. The buffer is not particularly limited as long as it is a compound having pH buffering ability.

Examples of the buffer may include Good's buffer. Specific examples of Good's buffer may include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl)methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris (hydroxymethyl)methylamino]-2-hydroxypropanesulfonic acid (TAPSO), piperazine-1,4-bis(2-hydroxypropanesulfonic acid) (POPSO), 4-(2-hydroxyethyl)piperazine-1-(2-hydroxypropane-3-sulfonic acid) (HEPSO), 4-(2-hydroxyethyl)-1-piperazinepropanesulfonic acid (EPPS), and the like.

The buffer may be used alone or in combination of two or more. Alternatively, the processing solution according to the present embodiment may not contain a buffer.

### (Surfactant)

The processing solution according to the present embodiment may contain a surfactant for the purpose of adjusting wettability of the processing solution to a substrate; and the like. Examples of the surfactant may include a nonionic surfactant, an anionic surfactant, a cationic surfactant, an amphoteric surfactant, etc.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, an acetylene polyalkylene oxide-based surfactant, and the like.

Examples of the anionic surfactant may include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, fatty acid, a salt thereof, and the like. Examples of the salt may include, but are not particularly limited to, a sodium salt, a potassium salt, an ammonium salt, an alkylammonium salt (e.g., a tetramethylammonium salt, etc.), and the like.

Examples of the cationic surfactant may include an alkylpyridium-based surfactant, a quaternary ammonium salt-based surfactant, and the like.

Examples of the amphoteric surfactant may include a betaine-type surfactant, an amino acid-type surfactant, an imidazoline-type surfactant, an amine oxide-type surfactant, and the like.

These surfactants are generally commercially available. These surfactants may be used alone or in combination of two or more.

When the processing solution according to the present embodiment contains a surfactant, the content of the surfactant is not particularly limited and is preferably from 0.0001 to 5% by mass with respect to the total mass of the processing solution, for example. The lower limit of the content thereof is more preferably 0.0002% by mass or more, and even more preferably 0.002% by mass or more. The upper limit of the content thereof is more preferably 3% by mass or less, even more preferably 1% by mass or less, and still even more preferably 0.2% by mass or less.

The processing solution according to the present embodiment may not contain one or more kinds of surfactant selected from the group consisting of the nonionic surfactant, the anionic surfactant, the cationic surfactant, and the amphoteric surfactant, and may not contain one or more of the above compounds exemplified as these surfactants. The processing solution according to the present embodiment may not contain a surfactant.

### (Impurity, Etc.)

The processing solution according to the present embodiment may contain a metal impurity containing at least one metal atom selected from the group consisting of a Fe atom, a Cr atom, a Ni atom, a Zn atom, a Ca atom, a Pb atom, etc., for example.

The total content of the metal atom in the processing solution according to the present embodiment is preferably 100 ppt by mass or less with respect to the total mass of the processing solution. The lower the lower limit of the total content of the metal atom, the more preferable it is. For example, the lower limit may be 0.001 ppt by mass or more. The total content of the metal atom may for example be from 0.001 to 100 ppt by mass. It is considered that the total content of the metal atom equal to or lower than the above preferred upper limit improves defect suppression properties and residue suppression properties of the processing solution. It is considered that, with the total content of the metal atom equal to or higher than the above preferred lower limit, the metal atom is less likely to be a free atom in the system and less likely to have a negative impact on the production yield of an entire object to be processed.

The content of the metal impurity can be adjusted by, for example, a purification process such as filtering, etc. The purification process such as filtering, etc. may be performed on a part or all of the raw materials before preparation of the processing solution, or may be performed after preparation of the processing solution.

The processing solution according to the present embodiment may contain, for example, an impurity derived from an organic substance (organic impurity). The total content of the above organic impurity in the processing solution according to the present embodiment is preferably 5000 ppm by mass or less. The lower the lower limit of the total content of the organic impurity, the more preferable it is. For example, the lower limit may be 0.1 ppm by mass or more. Examples of the total content of the organic impurity may include from 0.1 to 5000 ppm by mass.

The processing solution according to the present embodiment may contain an object to be counted of such a size as counted by a light scattering liquid-borne particle counter, for example. The size of the object to be counted is, for example, 0.04 μm or more. The number of the object to be counted contained in the processing solution according to the present embodiment is, for example, 1000 or less per 1 mL of the processing solution, and the lower limit thereof is, for example, 1 or more. It is considered that the number of the object to be counted in the processing solution within the above-described range improves a metal corrosion suppression effect of the processing solution.

The organic impurity and/or the object to be counted may be added to the processing solution or may be inevitably mixed in the processing solution in the manufacturing process of the processing solution. As non-limiting examples of the case that the organic impurity and/or the object to be counted is inevitably mixed in the processing solution in the manufacturing process of the processing solution, the organic impurity may be contained in a raw material (for example, an organic solvent) used for manufacturing the processing solution, or may be mixed in from an external environment in the manufacturing process of the processing solution (for example, contamination).

In the case that the object to be counted is added to the processing solution, the presence ratio may be adjusted for each specific size in consideration of surface roughness of an object to be processed, and the like.

### (Solvent)

The processing solution according to the present embodiment may contain a solvent. As the solvent, it preferably contains water, for example. The processing solution according to the present embodiment can be suitably used as an aqueous processing solution. For example, one example of that case may be an aqueous processing solution containing water as the remaining part other than the active ingredients.

The content of the water in the processing solution according to the present embodiment is not particularly limited, but is preferably from 1 to 99.99% by mass. From the viewpoint that the residue removal properties and anticorrosion properties can be maintained at high levels while imparting water solubility as an aqueous processing solution, the lower limit of the content thereof is more preferably 50% by mass or more, even more preferably 60% by mass or more, still even more preferably 70% by mass or more, still even more preferably 80% by mass or more, still even more preferably 90% by mass or more, and still even more preferably 95% by mass or more. In addition, from the viewpoint that the residue removal properties and anticorrosion properties can be maintained at high levels while imparting water solubility as an aqueous processing solution, the upper limit of the content thereof is more preferably 99.9% by mass or less, even more preferably 99% by mass or less, and still even more preferably 98.8% by mass or less. With the water content within the range described above, another component can be dissolved uniformly and stably.

The processing solution according to the present embodiment may contain an organic solvent. Specific examples of the organic solvent may include, but are not particularly limited to, at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent. Furthermore, it is preferable the processing solution according to the present embodiment contain only at least one selected from the group consisting of an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent, and do not contain a solvent other than these. Further, when the processing solution according to the present embodiment contains an organic solvent, it is preferable to use a water-soluble organic solvent from the viewpoint of water solubility of the processing solution.

Specific examples of the alcohol-based solvent may include aliphatic alcohols such as methanol, ethanol, modified ethanol, isopropanol, n-propanol, n-butanol, 3-methoxy-3-methyl-1-butanol, etc.; glycols such as ethylene glycol (also known as 1,2-ethanediol, monoethylene glycol), diethylene glycol (also known as 2,2′-oxydiethanol, diethyl glycol), propylene glycol (also known as propane-1,2-diol), dipropylene glycol, glycerin, 1,3-propanediol, 1,3-butanediol, 1,4-butanediol, furfuryl alcohol, hexylene glycol (also known as 2-methyl-2,4-pentanediol), etc.; and the like.

Specific examples of the glycol ester-based solvent may include ethylene-based glycol ether such as ethylene glycol monomethyl ether, ethylene glycol dimethyl ether, diethylene glycol monomethyl ether, diethylene glycol dimethyl ether, triethylene glycol monomethyl ether, triethylene glycol dimethyl ether, ethylene glycol monoethyl ether, ethylene glycol diethyl ether, ethylene glycol monobutyl ether, ethylene glycol dibutyl ether, diethylene glycol monobutyl ether, diethylene glycol dibutyl ether, triethylene glycol monobutyl ether, triethylene glycol dibutyl ether, ethylene glycol monohexyl ether, ethylene glycol dihexyl ether, diethylene glycol monohexyl ether, diethylene glycol dihexyl ether, ethylene glycol-phenyl ether, etc.; ethylene-based glycol ether acetates such as ethylene glycol monobutyl ether acetate, diethylene glycol monobutyl ether acetate, etc.; propylene-based glycol ether such as propylene glycol monomethyl ether (PGME), propylene glycol dimethyl ether, dipropylene glycol monomethyl ether (DPM), dipropylene glycol dimethyl ether, tripropylene glycol monomethyl ether, tripropylene glycol dimethyl ether, propylene glycol monoethyl ether, propylene glycol diethyl ether, dipropylene glycol monoethyl ether, dipropylene glycol diethyl ether, tripropylene glycol monoethyl ether, tripropylene glycol diethyl ether, propylene glycol monopropyl ether, propylene glycol dipropyl ether, dipropylene glycol monopropyl ether, dipropylene glycol dipropyl ether, propylene glycol monobutyl ether, propylene glycol dibutyl ether, dipropylene glycol monobutyl ether, dipropylene glycol dibutyl ether, tripropylene glycol monobutyl ether, tripropylene glycol dibutyl ether, propylene glycol phenyl ether, etc.; propylene-based glycol ether acetates such as propylene glycol methyl ether acetate, dipropylene glycol methyl ether acetate, propylene glycol diacetate, etc.; and the like.

Specific examples of the sulfoxide-based solvent may include dimethyl sulfoxide (DMSO), diethyl sulfoxide, dipropyl sulfoxide, diphenyl sulfoxide, thiophene, and the like.

Specific examples of the sulfone-based solvent may include dimethyl sulfone, diethyl sulfone, tetramethylene sulfone, dipropyl sulfone, sulfolane (also known as tetramethylene sulfone), 3-methylsulfolane, 2,4-dimethylsulfolane, 3,4-dimethylsulfolane, diphenylsulfolane, 3,4-diphenylmethylsulfolane, sulfolene, 3-methylsulfolene, 3-ethylsulfolene, and the like.

Specific examples of the amide-based solvent may include dimethylformamide (DMF), diethylformamide (DEF), dimethylacetamide (DMAc), N-methylpyrrolidine (MPD), hexamethylphosphate triamide (HMPA), and the like.

Specific examples of the lactone-based solvent may include γ-butyllactone, α-methyl-γ-butyrolactone, β-propiolactone, γ-valerolactone, δ-valerolactone, γ-caprolactone, ε-caprolactone, γ-laurolactone, hexanolactone, and the like.

Specific examples of the imidazolidinone-based solvent may include 2-imidazolidinone, 1,3-dimethyl-2-imidazolidinone, 1,3-diethyl-2-imidazolidinone, 1,3-dipropyl-2-imidazolidinone, 1,3-diisopropyl-2-imidazolidinone, and the like.

Specific examples of the nitrile-based solvent may include acetonitrile, propionitrile, valeronitrile, butyronitrile, and the like.

Specific examples of the ketone-based solvent may include acetone, methyl ethyl ketone (MEK), methyl isobutyl ketone (MIBK), diisobutyl ketone, cyclohexanone, diacetone alcohol, 1-hexanone, 2-hexanone, 4-heptanone, 2-heptanone (methylamyl ketone), 1-octanone, 2-octanone, 1-nonanone, 2-nonanone, acetylacetone, acetonyl acetone, phenylacetone, acetophenone, methylnaphthyl ketone, methylcyclohexanone, ionone, isophorone, propylene carbonate, diacetonyl alcohol, acetylcarbinol, and the like.

Specific examples of the ether-based solvent may include diisopropyl ether, 1,4-dioxane, methyl-tert-butyl ether (MTBE), dimethyl ether, diethyl ether, dipropyl ether, methylphenyl ether, and the like.

Specific examples of the ester-based solvent may include methyl acetate, ethyl acetate, butyl acetate, amyl acetate, propyl acetate, isopropyl acetate, methyl lactate, ethyl lactate, butyl lactate, ethyl methoxyacetate, ethyl ethoxyacetate, acetic acid 2-methoxybutyl (2-methoxybutyl acetate), acetic acid 3-methoxybutyl (3-methoxybutyl acetate), acetic acid 4-methoxybutyl (4-methoxybutyl acetate), acetic acid 3-methoxy-3-methylbutyl (3-methoxy-3-methylbutyl acetate), acetic acid 3-ethyl-3-methylbutyl (3-ethyl-3-methoxybutyl acetate), 4-methyl-4-methoxypentyl acetate, methyl formate, ethyl formate, propyl formate, butyl formate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, and the like.

Specific examples of the pyrrolidone-based solvent may include N-methylpyrrolidone (NMP), 2-pyrrolidone, N-vinyl-2-pyrrolidone, and the like.

Specific examples of the urea-based solvent may include 1,3-dimethylurea, 1,3-diethylurea, 1,3-dipropylurea, 1,3-diisopropylurea, tetramethylurea, tetraethylurea, tetrapropylurea, tetraisopropylurea, N,N-dimethylpropylene urea, and the like.

Among the above, the organic solvent is preferably a water-soluble organic solvent. Among the above specific examples, preferred examples of the water-soluble organic solvent may include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, hexylene glycol (also known as 2-methyl-2,4-pentanediol), etc.; glycol ester-based solvents such as diethylene glycol monobutyl ether, propylene glycol monomethyl ether, etc.; dimethyl sulfoxide; ethers such as ethylene glycol dimethyl ether, diethylene glycol dimethyl ether, triethylene glycol dimethyl ether, tetraethylene glycol dimethyl ether, propylene glycol dimethyl ether, etc.; morpholins such as N-methylmorpholine N-oxide, etc.; and the like. Among them, more preferred examples thereof may include hexylene glycol (also known as 2-methyl-2,4-pentanediol), and the like.

By using such a preferred solvent, for example, the anticorrosion properties of a layer containing a metal component such as cobalt, copper, tungsten, ruthenium, aluminum, molybdenum, etc. as a main component (for example, metal wiring layer 20, etching stop layer 30, interlayer insulating film 40, another functional layer, etc.) can be further improved. That is, when such a solvent is used, damage (film loss) caused to the layer containing cobalt, etc. can be more effectively reduced without impairing removability of a titanium-based residue.

The organic solvent may be used alone or in combination of two or more.

Although the processing solution according to the present embodiment can be expected to have a sufficient effect even if it does not contain an organic solvent, it can be expected to have a sufficient effect even if it contains an organic solvent. That is, the processing solution according to the present embodiment may contain an organic solvent. From such viewpoints, the content of the organic solvent in the present embodiment can be from 0 to 95% by mass. The lower limit of the content of the organic solvent in the processing solution may be 0% by mass; or may be, for example, 5% by mass or more, 10% by mass or more, 20% by mass or more, 30% by mass or more, 40% by mass or more, 50% by mass or more, or 60% by mass or more, depending on a component of the processing solution, etc. The upper limit of the content of the organic solvent in the processing solution may be, for example, 90% by mass or less, 80% by mass or less, or 70% by mass or less.

Here, an exemplary semiconductor substrate to which the processing solution according to the present embodiment can be used will be described.

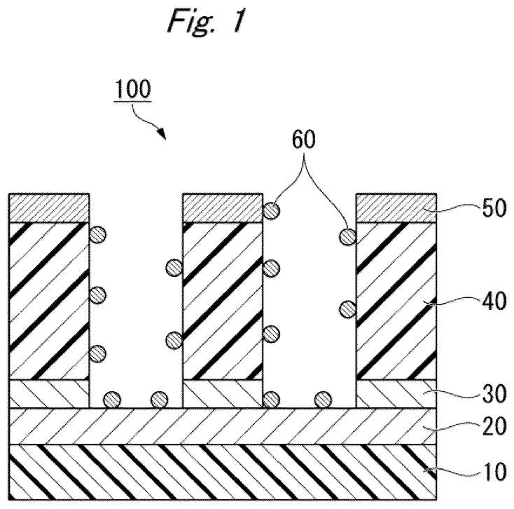

FIG. 1 is a cross-sectional view illustrating an exemplary element (semiconductor substrate) to be processed after dry etching.

A semiconductor element 100 illustrated in FIG. 1 includes a substrate 10, a metal wiring layer 20, an etching stop layer 30, and an interlayer insulating film 40, which are laminated in this order, and a hard mask layer (HM layer) 50 is formed on the interlayer insulating film 40 (substrate 10/metal wiring layer 20/etching stop layer 30/interlayer insulating film 40/HM layer 50).

The semiconductor element 100 has been subjected to dry etching in a wiring process. That is, the semiconductor is in a state after the dry etching of the interlayer insulating film 40 by using as a mask the HM layer 50 having a basic shape of a wiring pattern formed by dry etching. Dry etching residues 60 are adhered to side surfaces of the HM layer 50 and the interlayer insulating film 40. Here, a case of dry etching is described as an example. For example, in a case of wet etching, the resultant residue is a wet etching residue.

The metal wiring layer 20 and the etching stop layer 30 are exposed to spaces in the interlayer insulating film 40 in the shape of the wiring pattern, and the dry etching residues 60 are also adhered.

As the substrate 10, for example, a substrate made of a material such as silicon, amorphous silicon, glass, or the like can be used.

The metal wiring layer 20 is a wiring layer containing one of metals such as molybdenum (Mo), tungsten (W), ruthenium (Ru), copper (Cu), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc. and a metal oxide, a metal nitride, a metal chloride, a metal fluoride, etc. thereof.

Note that the metal wiring layer 20 is not limited to wiring and broadly includes those functioning as a functional layer such as an electrode, an insulating layer, a low dielectric layer, and various conductor layers. It includes a layer formed by using the metals mentioned above and a metal oxide, a metal nitride, a metal chloride, a metal fluoride, etc. thereof. For example, in the case of a silicon-based metal wiring layer, a SiN, SiO₂, or Low-k film (SiOC film, SiCOH film, etc.), ILD, and the like can be exemplified.

A material of the interlayer insulating film 40 may be any material as long as it has insulating properties. The material is not particularly limited, and a suitable material may be appropriately selected in consideration of a manufacturing condition and the like. As the interlayer insulating film 40, for example, a layer containing a silicon-based material such as SiO₂, SiN, SiOC, SiOCN, etc. can be used.

A material of the HM layer 50 may be any material as long as it acts as a protective film against etching. The material is not particularly limited, and a suitable material may be appropriately selected in consideration of a manufacturing condition and the like. As the HM layer 50, a protective film containing a titanium atom, that is, a titanium-based metal protective film may be suitably used. The processing solution according to the present embodiment can efficiently remove the HM layer 50, and can also efficiently remove an etching residue (refer to the dry etching residue 60, for example). The dry etching residue 60 is mainly a residue including a titanium-based metal derived from the HM layer 50, but is not limited to such a residue. The dry etching residue 60 also includes, for example, an etching residue containing the above-described inorganic substance, and the like.

### Method for Processing a Substrate

The processing solution according to the present embodiment can be suitably used as a method for processing a substrate. A method for processing a substrate according to the present embodiment is a method for processing a substrate, including: etching a substrate including a protective film containing a titanium atom, and a metal layer containing a silicon atom; and processing the etched substrate using the processing solution described above. For example, in the case of the semiconductor element 100 (semiconductor substrate) illustrated in FIG. 1, the HM layer 50 corresponds to the protective film. Hereinafter, a case of cleaning the semiconductor element 100 illustrated in FIG. 1 will be described as an example.

The method for processing the substrate according to the present embodiment is a step of processing the semiconductor element 100 after dry etching is performed in a wiring process, using the processing solution described above. Examples of the processing here may include removing the HM layer 50, cleaning and removing the dry etching residue 60, and the like.

When bringing the processing solution into contact with the semiconductor element 100 to be processed, the processing solution may be diluted 2 to 2000 times to obtain a diluted solution, and a cleaning operation may then be performed using the diluted solution.

Examples of the processing operation may include a method of continuously discharging the processing solution on the semiconductor element 100 rotating at a constant speed (rotational application method), a method of immersing the semiconductor element 100 in the processing solution for a certain period of time (dipping method), a method of spraying the processing solution on a surface of the semiconductor element 100 (spraying method), and the like.

A processing temperature is not particularly limited, but the processing is preferably performed under the condition of 10 to 80° C. The lower limit of the cleaning processing temperature (the temperature of the processing solution) is more preferably 20° C. or more, and even more preferably 40° C. or more. The upper limit of the cleaning processing temperature (the temperature of the processing solution) is more preferably 75° C. or less, and even more preferably 70° C. or less. With the lower limit of the cleaning processing temperature within the range described above, the balance between the removal of the HM layer 50 and suppression of damage to various functional layers other than the HM layer 50 (metal wiring layer 20, etching stop layer 30, interlayer insulating film 40, and the like) can be further improved. With the upper limit of the processing temperature within the range described above, it is possible to more effectively suppress an unintentional change in the composition of the processing solution, and the processing can be more efficient from the viewpoint of workability, safety, cost, and the like.

Processing time can be appropriately selected so as to be sufficient for removing the HM layer 50 and removing an etching residue, other impurities, and the like adhered on a surface of the semiconductor element 100. For example, the processing time is preferably from 10 seconds to 30 minutes. The lower limit of the processing time is more preferably 20 seconds or more, and even more preferably 30 seconds or more. The upper limit of the processing time is more preferably 15 minutes or less, even more preferably 10 minutes or less, and still even more preferably 5 minutes or less.

Since the processing solution according to the present embodiment is used for cleaning, in the semiconductor element 100 to which the dry etching residues 60 are adhered, the dry etching residues 60 derived from the HM layer 50, which is a protective film, can be well cleaned and removed while damage to the metal wiring layer 20 is suppressed. In particular, in the case of a HM layer 50 containing titanium and/or a titanium alloy, the processing solution according to the present embodiment is particularly suitable since it is excellent in removability of the HM layer 50.

Furthermore, since the processing solution according to the present embodiment can achieve the removal of the HM layer 50 and suppression of damage to various functional layers other than the HM layer 50 (metal wiring layer 20, etching stop layer 30, interlayer insulating film 40, and the like) without using conventionally commonly used hydrogen fluoride, hydrogen peroxide, hydroxylamine, etc., an advantage can also be expected that a semiconductor element and the like can be manufactured more safely.

### Method for Manufacturing a Semiconductor Substrate

The processing solution according to the present embodiment and the processing method using the same can be suitably used as a method for manufacturing a semiconductor substrate. A method for manufacturing a semiconductor substrate according to the present embodiment is a method for manufacturing a semiconductor substrate, including: etching a substrate including a protective film containing a titanium atom, and a metal layer containing a silicon atom; and processing the etched substrate using the processing solution described above. For example, in the case of the semiconductor element 100 (semiconductor substrate) illustrated in FIG. 1, the HM layer 50 corresponds to the protective film, as in the description of the processing method above. Hereinafter, a case of cleaning the semiconductor element 100 illustrated in FIG. 1 will be described as an example.

### (1) Step of Preparing a Substrate Having a Protective Film

In step (1), a substrate having at least a protective film is prepared. Although not illustrated, in the case of FIG. 1, a laminate before etching that has in this order a substrate 10, a metal wiring layer 20, an etching stop layer 30, an interlayer insulating film 40, and a hard mask layer (HM layer) 50 corresponding to the protective film is prepared (substrate 10/metal wiring layer 20/etching stop layer 30/interlayer insulating film 40/HM layer 50).

A method for sequentially forming, on the substrate 10, the metal wiring layer 20, the etching stop layer 30, the interlayer insulating film 40, and the hard mask layer (HM layer) 50 corresponding to the protective film is not particularly limited, and a known method can be employed depending on the kind of a metal used, etc. Examples of the forming method may include a chemical vapor deposition method (CVD method), a physical vapor deposition method (PVD), an atomic layer deposition method (ALD method), and the like.

### (2) Step of Etching the Protective Film

Subsequently, the HM layer 50, which is the protective film, is subject to etching. An etching method is not particularly limited, may be wet etching or dry etching, but is preferably dry etching. Dry etching is advantageous from the viewpoint that a metal wiring at nano level is possible, and gas used can be controlled. In the case of dry etching, there is a concern that damage to the substrate, etc. is relatively large, but from the viewpoint that such damage can be effectively suppressed by using the processing solution according to the present embodiment, dry etching is also desirable in a point that the advantage of the present embodiment can be more effectively reflected.

In the case of dry etching, plasma can be used. Usually, when plasma etching is performed, there is a problem that the substrate is easily damaged, or a problem that plasma etching generates a plasma etching residue and it is necessary to clean it with a processing solution. However, dry etching is also preferable in a point that such problems can be effectively suppressed by using the processing solution according to the present embodiment.

(3) Step of Removing an Impurity from the Substrate by Bringing the Above Processing Solution into Contact with the Substrate, after Etching

As the step (3), the processing methods described above can be used. Thereby, the semiconductor element 100 can be obtained. As necessary, a known post-processing can be performed after the cleaning.

As described above, the processing solution according to the present embodiment can be used, for example, as a processing solution used in a semiconductor etching step, etc., and in particular, the processing solution according to the present embodiment is suitable for dry etching.

A processing solution containing hydrogen fluoride, a processing solution containing hydroxylamine, a processing solution containing hydrogen peroxide, and the like that have been conventionally used have a problem that damage to a titanium-based metal protective film (film loss) is large and balancing with suppression of damage to a pattern is difficult. However, the processing solution according to the present embodiment can solve the problem. Furthermore, the processing solution according to the present embodiment can be expected to impart anticorrosion properties to a wide range of metals by using in combination (by containing) an anticorrosive agent as necessary.

### <<Second Aspect of Processing Solution>>

As a second aspect of the processing solution according to the present embodiment, a processing solution containing 2,3,5-triphenyltetrazolium chloride (TPT Cl) as an anticorrosive agent is provided. The processing solution of the second aspect surprisingly has an advantage of being particularly excellent in the anticorrosion properties of molybdenum. Preferred examples of the processing solution of the second aspect may include, for example, the following:

<1> A processing solution, including: 2,3,5-triphenyltetrazolium chloride as an anticorrosive agent.
<2> The processing solution according to <1>, further including: water as a solvent.
<3> The processing solution according to <2>, in which a pH value of the processing solution is 3.5 or less.
<4> The processing solution according to <1>, further including: at least one selected from the group consisting of iodic acid, and periodic acid as an oxidizing agent (A).
<5> The processing solution according to <1>, further including: iodic acid as an oxidizing agent.
<6> The processing solution according to <4>, further including: hexafluorosilicic acid (B), in which a molar ratio of a Si atom of the hexafluorosilicic acid (B) to the content of the oxidizing agent (A) is from 8 to 1900.
<7> The processing solution according to <1>, further including: at least one selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, a phenanthroline ring-containing compound, a benzothioazole ring-containing compound, an oxindole, and tetraalkyl indolium iodide as an anticorrosive agent other than 2,3,5-triphenyltetrazolium chloride.
<8> The processing solution according to <1>, in which the processing solution is a processing solution for a substrate including a metal layer containing a molybdenum atom.
<9> A method for processing a substrate, including: etching a substrate including a metal layer containing a molybdenum atom; and processing the etched substrate using the processing solution according to <1>.
<10> A method for manufacturing a semiconductor substrate, including: etching a substrate including a metal layer containing a molybdenum atom; and processing the etched substrate using the processing solution according to <1>.

For the contents of <1> to <10> above, the contents, conditions, etc. described in the first aspect may be appropriately adopted to the elements common to the processing solution of the first aspect, the method for processing the substrate using the same, and the method for manufacturing the semiconductor substrate.

Similarly to the processing solution of the first aspect, since the processing solution according to the second aspect can achieve suppression of damage to a pattern of the above-mentioned functional layers without using conventionally commonly used hydrogen fluoride, hydroxylamine, etc., an advantage can also be expected that a semiconductor element and the like can be manufactured more safely.

### EXAMPLES

The present invention will be described in more detail with reference to the following Examples and Comparative examples, but the present invention is not limited in any way to the following examples.

Abbreviations are as follows unless otherwise specified.
HIO₃: iodic acid
HF: hydrogen fluoride
HFSA: hexafluorosilicic acid
MSA: methanesulfonic acid
TPT Cl: 2,3,5-triphenyltetrazolium chloride
5MBTA: 5-methyl-1H-benzotriazole
NH₄OH: ammonium hydroxide
TEOS: tetraethoxysilane

### Test 1: Examples 1 to 13, Comparative Examples 1 to 20

### 1-1. Preparation of Processing Solutions

By blending the components and water (DIW) in the proportions shown in Tables 1 and 2, processing solutions of Examples and Comparative examples were obtained. Note that “%” and “ppm” in the tables are based on mass unless otherwise specified.

For example, Example 1 is a processing solution with a pH of 1.8 that contains 5 ppm by mass of HIO₃, 0.20% by mass of HFSA, 1.0% by mass of MSA, 1.0% by mass of TPT Cl, 0.3% by mass of 5MBTA, and water as the rest. In the processing solution of Example 1, the molar ratio of the content of the hexafluorosilicic acid to the content of the oxidizing agent (Si/oxidizing agent (molar ratio)) is 488.

Comparative example 1 is a processing solution with a pH of 1.8 that contains 100 ppm by mass of HIO₃, 0.3% by mass of HF, 1.0% by mass of MSA, and water as the rest. Since the processing solution of Comparative example 1 does not contain hexafluorosilicic acid, the molar ratio of the content of the hexafluorosilicic acid to the content of the oxidizing agent (Si/oxidizing agent (molar ratio)) is “0”.

The pH of each processing solution of Examples and Comparative examples was measured using a pH/ORP meter (portable pH meter “ORION STAR A324”, manufactured by Thermo Scientific) under a temperature condition of 22° C.

### 1-2. Evaluation of Etching Rates of TiN, TEOS, W, and Mo

Etching rates of TiN, TEOS, W, and Mo were evaluated by the following method. First, laminates having respective layers on substrates (substrates having a film) were prepared as below.
A laminate in which a TiN layer (film thickness: 20 nm) is formed on a substrate (12-inch silicon substrate) was prepared by a CVD method.
A laminate in which a TEOS layer (film thickness: 100 nm) is formed on a substrate (12-inch silicon substrate) was prepared by the CVD method.
A laminate in which a W layer (film thickness: 100 nm) is formed on a substrate (12-inch silicon substrate) was prepared by the CVD method.
A laminate in which a Mo layer (film thickness: 40 nm) is formed on a substrate (12-inch silicon substrate) was prepared by a PVD method.

Subsequently, the laminates obtained (the substrates having the film) were cut into 2 cm×2 cm in top view to obtain test samples (wafer coupons). The samples were immersed in the respective processing solutions of Examples and Comparative examples at 58° C. for 2 minutes (for Ti) or 5 minutes (for TEOS, W, and Mo). After the immersion, the samples were taken out from the processing solutions, washed with isopropyl alcohol, and then dried by nitrogen blowing at room temperature to obtain samples (substrates for measurement after etching).

The etching rates (ER: film loss) of TiN, TEOS, W, and Mo of the obtained samples (the substrates for measurement after etching) were determined. The etching rates were evaluated by measuring the amount of film thickness removed (the amount of film loss) per unit time.

For TiN and TEOS, the film thickness was determined at three points within a surface of the sample using a spectroscopic ellipsometer (device name “L115S”, manufactured by GAERTNER SCIENTIFIC), and the average value was taken as the film thickness.

For W and Mo, the film thickness was determined using an X-ray fluorescence spectrometer (XRF, device name “ZSX Primus IV”, manufactured by Rigaku Corporation). Specifically, for a metal layer having a predetermined film thickness, the amount of metal in the metal layer was quantitatively measured using the XRF, and a calibration curve was prepared for the relationship between the film thickness and the amount of metal. Then, for the metal layer of the sample, the metal layer was quantitatively analyzed using the XRF, and the film thickness was determined based on the calibration curve.

For example, for TiN, the amount of film loss in 2 minutes is evaluated in “nm/min”, and the higher the etching rate, the better and more excellent the removability. For TEOS, W, and Mo, the amount of film loss in 5 minutes is evaluated in “nm/min”, and the lower the etching rate, the better and more excellent the anticorrosion properties.

Table 1 shows the compositions of the processing solutions of Examples. Table 2 shows the compositions of the processing solutions of Comparative examples. Table 3 shows the evaluation results of Examples. Table 4 shows the evaluation results of Comparative examples. “%” and “ppm” in the tables are based on mass unless otherwise specified. “ND” in Table 4 indicates that no measurement was carried out (No data).

TABLE 1

| | | | Si/Oxidizing | | | | |
|---|---|---|---|---|---|---|---|
| | Oxidizing | | agent | pH | Anticorrosive | Anticorrosive | |
| | agent | Etchant | (molar ratio) | adjuster | agent 1 | agent 2 | pH |
| Example 1 | HIO₃ 5 ppm | HFSA 0.20% | 488 | MSA 1.0% | TPT CI 1.0% | 5MBTA 0.3% | 1.8 |
| Example 2 | HIO₃ 5 ppm | HFSA 0.36% | 879 | MSA 1.0% | TPT CI 1.0% | 5MBTA 0.3% | 1.8 |
| Example 3 | HIO₃ 10 ppm | HFSA 0.20% | 244 | MSA 1.0% | TPT CI 1.0% | 5MBTA 0.3% | 1.8 |
| Example 4 | HIO₃ 10 ppm | HFSA 0.36% | 440 | MSA 1.0% | TPT CI 1.0% | 5MBTA 0.3% | 1.8 |
| Example 5 | HIO₃ 10 ppm | HFSA 0.80% | 977 | MSA 1.0% | TPT CI 1.0% | 5MBTA 0.3% | 1.8 |
| Example 6 | HIO₃ 25 ppm | HFSA 0.025% | 8 | MSA 1.0% | TPT CI 1.0% | 5MBTA 0.3% | 1.8 |
| Example 7 | HIO₃ 50 ppm | HFSA 0.20% | 49 | MSA 1.0% | TPT C1 1.0% | 5MBTA 0.3% | 1.8 |
| Example 8 | HIO₃ 50 ppm | HFSA 0.36% | 88 | MSA 1.0% | TPT CI 1.0% | 5MBTA 0.3% | 1.8 |
| Example 9 | HIO₃ 50 ppm | HFSA 0.80% | 195 | MSA 1.0% | TPT CI 1.0% | 5MBTA 0.3% | 1.8 |
| Example 10 | HIO₃ 50 ppm | HFSA 1.20% | 293 | MSA 1.0% | TPT CI 1.0% | 5MBTA 0.3% | 1.8 |
| Example 11 | HIO₃ 500 ppm | HFSA 0.36% | 9 | MSA 1.0% | TPT CI 1.0% | 5MBTA 0.3% | 1.8 |
| Example 12 | HIO₃ 500 ppm | HFSA 0.80% | 20 | MSA 1.0% | TPT CI 1.0% | 5MBTA 0.3% | 1.8 |
| Example 13 | HIO₃ 500 ppm | HFSA 1.20% | 29 | MSA 1.0% | TPT CI 1.0% | 5MBTA 0.3% | 1.8 |

TABLE 2

| | | | Si/Oxidizing | | | | |
|---|---|---|---|---|---|---|---|
| | Oxidizing | | agent (molar | pH | Anticorrosive | Anticorrosive | |
| | agent | Etchant | ratio) | adjuster | agent 1 | agent 2 | pH |
| Comparative | HIO₃ | HF 0.3% | 0 | MSA 1.0% | — | — | 1.8 |
| example 1 | 100 ppm | | | | | | |
| Comparative | HIO₃ | HF 0.3% | 0 | MSA 5.0% | TPT CI 1.0% | 5MBTA 0.3% | 1.3 |
| example 2 | 50 ppm | | | | | | |
| Comparative | HIO₃ | HF 0.1% | 0 | MSA 5.0% | TPT CI 1.0% | 5MBTA 0.3% | 1.3 |
| example 3 | 100 ppm | | | | | | |
| Comparative | HIO₃ | HF 0.2% | 0 | MSA 5.0% | TPT CI 1.0% | 5MBTA 0.3% | 1.3 |
| example 4 | 100 ppm | | | | | | |
| Comparative | HIO₃ | HF 0.3% | 0 | MSA 5.0% | TPT CI 1.0% | 5MBTA 0.3% | 1.3 |
| example 5 | 100 ppm | | | | | | |
| Comparative | HIO₃ | HF 0.4% | 0 | MSA 5.0% | TPT CI 1.0% | 5MBTA 0.3% | 1.3 |
| example 6 | 100 ppm | | | | | | |
| Comparative | HIO₃ | HF 0.3% | 0 | MSA 5.0% | TPT CI 1.0% | 5MBTA 0.3% | 1.3 |
| example 7 | 250 ppm | | | | | | |
| Comparative | HIO₃ | HF 0.3% | 0 | MSA 5.0% | TPT CI 1.0% | 5MBTA 0.3% | 1.3 |
| example 8 | 500 ppm | | | | | | |
| Comparative | HIO₃ | HF 0.3% | 0 | MSA 5.0% | TPT CI 1.0% | 5MBTA 0.3% | 1.3 |
| example 9 | 750 ppm | | | | | | |
| Comparative | HIO₃ | HF 0.1% | 0 | MSA 5.0% | TPT CI 1.0% | 5MBTA 0.3% | 1.3 |
| example 10 | 1000 ppm | | | | | | |
| Comparative | HIO₃ | HF 0.2% | 0 | MSA 5.0% | TPT CI 1.0% | 5MBTA 0.3% | 1.3 |
| example 11 | 1000 ppm | | | | | | |
| Comparative | HIO₃ | HF 0.3% | 0 | MSA 5.0% | TPT CI 1.0% | 5MBTA 0.3% | 1.3 |
| example 12 | 1000 ppm | | | | | | |
| Comparative | HIO₃ | HF 0.4% | 0 | MSA 5.0% | TPT CI 1.0% | 5MBTA 0.3% | 1.3 |
| example 13 | 1000 ppm | | | | | | |
| Comparative | HIO₃ | HF 0.3% | 0 | MSA 5.0% | TPT CI 1.0% | 5MBTA 0.3% | 1.3 |
| example 14 | 1500 ppm | | | | | | |
| Comparative | HIO₃ | HF 0.3% | 0 | MSA 5.0% | TPT CI 1.0% | 5MBTA 0.3% | 1.3 |
| example 15 | 5000 ppm | | | | | | |
| Comparative | HIO₃ 5% | HF 0.3% | 0 | MSA 5.0% | TPT CI 1.0% | 5MBTA 0.3% | 1.3 |
| example 16 | | | | | | | |
| Comparative | HIO₃ | HFSA 0.80% | 1953 | MSA 1.0% | TPT CI 1.0% | 5MBTA 0.3% | 1.8 |
| example 17 | 5 ppm | | | | | | |
| Comparative | HIO₃ | HFSA 1.20% | 2930 | MSA 1.0% | TPT CI 1.0% | 5MBTA 0.3% | 1.8 |
| example 18 | 5 ppm | | | | | | |
| Comparative | HIO₃ | HFSA 1.20% | 1465 | MSA 1.0% | TPT CI 1.0% | 5MBTA 0.3% | 1.8 |
| example 19 | 10 ppm | | | | | | |
| Comparative | HIO₃ | HFSA 0.20% | 5 | MSA 1.0% | TPT CI 1.0% | 5MBTA 0.3% | 1.8 |
| example 20 | 500 ppm | | | | | | |

TABLE 3

| | ER | | | | |
|---|---|---|---|---|---|
| | TiN | | TEOS | W | Mo |
| | 2 min | | 5 min | 5 min | 5 min |
| Example 1 | 6.1 | nm/min | <1.0 nm/min | <1.0 nm/min | <1.0 nm/min |
| Example 2 | 7.4 | nm/min | <1.0 nm/min | <1.0 nm/min | <1.0 nm/min |
| Example 3 | 7.6 | nm/min | <1.0 nm/min | <1.0 nm/min | <1.0 nm/min |
| Example 4 | 7.6 | nm/min | <1.0 nm/min | <1.0 nm/min | <1.0 nm/min |
| Example 5 | 7.0 | nm/min | <1.0 nm/min | <1.0 nm/min | <1.0 nm/min |
| Example 6 | 5.0 | nm/min | <1.0 nm/min | <1.0 nm/min | <1.0 nm/min |
| Example 7 | 5.6 | nm/min | <1.0 nm/min | <1.0 nm/min | <1.0 nm/min |
| Example 8 | 7.2 | nm/min | <1.0 nm/min | <1.0 nm/min | <1.0 nm/min |
| Example 9 | 8.7 | nm/min | <1.0 nm/min | <1.0 nm/min | <1.0 nm/min |
| Example 10 | 10.0 | nm/min | <1.0 nm/min | <1.0 nm/min | <1.0 nm/min |
| Example 11 | 5.0 | nm/min | <1.0 nm/min | <1.0 nm/min | <1.0 nm/min |
| Example 12 | 5.9 | nm/min | <1.0 nm/min | <1.0 nm/min | <1.0 nm/min |
| Example 13 | 7.8 | nm/min | <1.0 nm/min | <1.0 nm/min | <1.0 nm/min |

TABLE 4

| | ER | | | | | | | |
|---|---|---|---|---|---|---|---|---|
| | TiN | | TEOS | | W | | Mo | |
| | 2 min | | 5 min | | 5 min | | 5 min | |
| Comparative | 19.3 | nm/min | 7.6 | nm/min | 19.1 | nm/min | 19.0 | nm/min |
| example 1 | | | | | | | | |
| Comparative | 5.2 | nm/min | 7.9 | nm/min | <1.0 | nm/min | 1.3 | nm/min |
| example 2 | | | | | | | | |
| Comparative | 9.4 | nm/min | 3.7 | nm/min | <1.0 | nm/min | >7.0 | nm/min |
| example 3 | | | | | | | | |
| Comparative | 14.5 | nm/min | 5.9 | nm/min | <1.0 | nm/min | 5.0 | nm/min |
| example 4 | | | | | | | | |
| Comparative | 17.7 | nm/min | 7.7 | nm/min | <1.0 | nm/min | 3.1 | nm/min |
| example 5 | | | | | | | | |
| Comparative | 10.6 | nm/min | 13.6 | nm/min | <1.0 | nm/min | <1.0 | nm/min |
| example 6 | | | | | | | | |
| Comparative | 19.4 | nm/min | ND | | <1.0 | nm/min | 5.4 | nm/min |
| example 7 | | | | | | | | |
| Comparative | 17.9 | nm/min | 7.9 | nm/min | <1.0 | nm/min | >7.0 | nm/min |
| example 8 | | | | | | | | |
| Comparative | 17.2 | nm/min | ND | | <1.0 | nm/min | >7.0 | nm/min |
| example 9 | | | | | | | | |
| Comparative | 7.0 | nm/min | 3.7 | nm/min | <1.0 | nm/min | 2.2 | nm/min |
| example 10 | | | | | | | | |
| Comparative | 10.6 | nm/min | 5.9 | nm/min | <1.0 | nm/min | >7.0 | nm/min |
| example 11 | | | | | | | | |
| Comparative | 16.1 | nm/min | 8.5 | nm/min | <1.0 | nm/min | >7.0 | nm/min |
| example 12 | | | | | | | | |
| Comparative | 19.4 | nm/min | 13.9 | nm/min | 1.0 | nm/min | >7.0 | nm/min |
| example 13 | | | | | | | | |
| Comparative | 13.9 | nm/min | ND | | <1.0 | nm/min | >7.0 | nm/min |
| example 14 | | | | | | | | |
| Comparative | 7.4 | nm/min | 8.0 | nm/min | ND | | ND | |
| example 15 | | | | | | | | |
| Comparative | <1.0 | nm/min | 8.6 | nm/min | ND | | ND | |
| example 16 | | | | | | | | |
| Comparative | 3.4 | nm/min | <1.0 | nm/min | <1.0 | nm/min | <1.0 | nm/min |
| example 17 | | | | | | | | |
| Comparative | 1.2 | nm/min | <1.0 | nm/min | <1.0 | nm/min | <1.0 | nm/min |
| example 18 | | | | | | | | |
| Comparative | 1.6 | nm/min | <1.0 | nm/min | <1.0 | nm/min | <1.0 | nm/min |
| example 19 | | | | | | | | |
| Comparative | 3.1 | nm/min | <1.0 | nm/min | <1.0 | nm/min | <1.0 | nm/min |
| example 20 | | | | | | | | |

### Test 2: Examples 14 to 17

### 2-1. Preparation of Processing Solutions

By blending the components and water in the proportions shown in Table 5, processing solutions of Examples were obtained. Note that “%” and “ppm” in the table are based on mass unless otherwise specified.

For example, Example 14 is a processing solution with a pH of 1.3 that contains 50 ppm by mass of HIO₃, 1.20% by mass of HFSA, 5.2% by mass of MSA, 1.0% by mass of TPT Cl, 0.3% by mass of 5MBTA, and water as the rest. In the processing solution of Example 14, the molar ratio of a Si atom of the hexafluorosilicic acid to the content of the oxidizing agent (Si/oxidizing agent (molar ratio)) is 293.

The pH of each processing solution of Examples and Comparative examples was measured using the same measuring method as in Test 1.

### 2-2. Evaluation of Etching Rates of TiN, TEOS, W, and Mo

In the same manner as in Test 1, samples were prepared. Then, in the same manner as in Test 1, the etching rates of TiN, TEOS, W, and Mo were measured.

2-3. Visual Evaluation of the Removability of Residues on Substrate after Cleaning

In the same manner as in Test 1, the residue removal properties were visually evaluated for each substrate after cleaning. As a result, for none of the metal layers of the substrates for measurement of Examples, corrosion to the extent that it would pose a practical problem was not confirmed.

Table 5 shows the compositions of Examples. Table 6 shows the evaluation results of Examples.

TABLE 5

| | | Si/Oxidizing | | | | | |
|---|---|---|---|---|---|---|---|
| | | agent (molar | Oxidizing | | pH | Anticorrosive | Anticorrosive |
| | pH | ratio) | agent | Etchant | adjuster | agent 1 | agent 2 |
| Example 14 | 1.3 | 293 | HIO₃ | HFSA | MSA 5.2% | TPT CI 1.0% | 5MBTA 0.3% |
| | | | 50 ppm | 1.20% | | | |
| Example 15 | 1.6 | 293 | HIO₃ | HFSA | MSA 1.1% | TPT CI 1.0% | 5MBTA 0.3% |
| | | | 50 ppm | 1.20% | | | |
| Example 16 | 1.8 | 293 | HIO₃ | HFSA | — | TPT CI 1.0% | 5MBTA 0.3% |
| | | | 50 ppm | 1.20% | | | |
| Example 17 | 2.7 | 293 | HIO₃ | HFSA | NH₄OH | TPT CI 1.0% | 5MBTA 0.3% |
| | | | 50 ppm | 1.20% | 0.26% | | |

TABLE 6

| | ER | | | | | |
|---|---|---|---|---|---|---|
| | TiN | | TEOS | W | Mo | |
| | 2 min | | 5 min | 5 min | 5 min | |
| Example 14 | 10.7 | nm/min | <1.0 nm/min | <1.0 nm/min | 3.4 | nm/min |
| Example 15 | 9.4 | nm/min | <1.0 nm/min | <1.0 nm/min | <1.0 | nm/min |
| Example 16 | 7.8 | nm/min | <1.0 nm/min | <1.0 nm/min | <1.0 | nm/min |
| Example 17 | 3.2 | nm/min | <1.0 nm/min | <1.0 nm/min | <1.0 | nm/min |

### Test 3: Examples 18 to 43

### 3-1. Preparation of Processing Solutions

By blending the components and water in the proportions shown in Table 7, processing solutions of Examples were obtained. Note that “%” and “ppm” in the table are based on mass unless otherwise specified.

For example, Example 18 is a processing solution with a pH of 1.8 that contains 25 ppm by mass of HIO₃, 0.025% by mass of HFSA, 1.0% by mass of MSA, 1.0% by mass of TPT Cl, 0.3% by mass of 5MBTA (5-methyl-1H-benzotriazole), and water as the rest. In the processing solution of Example 18, the molar ratio of a Si atom of the hexafluorosilicic acid to the content of the oxidizing agent (Si/oxidizing agent (molar ratio)) is 8.

The pH of each processing solution of Examples and Comparative examples was measured using the same measuring method as in Test 1.

### 3-2. Evaluation of Etching Rates of TiN, TEOS, W, and Mo

Samples were prepared in the same manner as in Test 1. Then, in the same manner as in Test 1, the etching rates of TiN, TEOS, W, and Mo were measured.

3-3. Visual Evaluation of the Removability of Residues on Substrate after Cleaning

In the same manner as in Test 1, the residue removal properties were visually evaluated for each substrate after cleaning. As a result, for none of the metal layers of the substrates for measurement of Examples, corrosion to the extent that it would pose a practical problem was not confirmed.

Table 7 shows the compositions of Examples. Table 8 shows the evaluation results of Examples. The compound “Benzotriazole (BTA)” in Table 7 refers to 1,2,3-benzotriazole.

TABLE 7

| | | | Si/Oxidizing | | Anticor- | | |
|---|---|---|---|---|---|---|---|
| | Oxidizing | | agent (molar | pH | rosive | | |
| | agent | Etchant | ratio) | adjuster | agent 1 | Anticorrosive agent 2 | pH |
| Example 18 | HIO₃ | HFSA | 8 | MSA 1.0% | TPT CI | 5MBTA 0.3% | 1.8 |
| | 25 ppm | 0.025% | | | 1.0% | | |
| Example 19 | HIO₃ | HFSA | 8 | MSA 1.0% | TPT CI | 2,6-Dimethylbenzothiazole 0.3% | 1.8 |
| | 25 ppm | 0.025% | | | 1.0% | | |
| Example 20 | HIO₃ | HFSA | 8 | MSA 1.0% | TPT CI | Benzotriazole (BTA) 0.3% | 1.8 |
| | 25 ppm | 0.025% | | | 1.0% | | |
| Example 21 | HIO₃ | HFSA | 8 | MSA 1.0% | TPT CI | 1H-1,2,3-Triazolo[4.5-b]pyridine | 1.8 |
| | 25 ppm | 0.025% | | | 1.0% | 0.3% | |
| Example 22 | HIO₃ | HFSA | 8 | MSA 1.0% | TPT CI | 1-Methyl-1H-benzotriazole 0.3% | 1.8 |
| | 25 ppm | 0.025% | | | 1.0% | | |
| Example 23 | HIO₃ | HFSA | 8 | MSA 1.0% | TPT CI | Indazole 0.3% | 1.8 |
| | 25 ppm | 0.025% | | | 1.0% | | |
| Example 24 | HIO₃ | HFSA | 8 | MSA 1.0% | TPT CI | Oxindole 0.3% | 1.8 |
| | 25 ppm | 0.025% | | | 1.0% | | |
| Example 25 | HIO₃ | HFSA | 8 | MSA 1.0% | TPT CI | 4-Fluoroindazole 0.3% | 1.8 |
| | 25 ppm | 0.025% | | | 1.0% | | |
| Example 26 | HIO₃ | HFSA | 8 | MSA 1.0% | TPT CI | 5-Nitroindazole 0.3% | 1.8 |
| | 25 ppm | 0.025% | | | 1.0% | | |
| Example 27 | HIO₃ | HFSA | 8 | MSA 1.0% | TPT CI | Indazole-3-carboxylic Acid 0.3% | 1.8 |
| | 25 ppm | 0.025% | | | 1.0% | | |
| Example 28 | HIO₃ | HFSA | 8 | MSA 1.0% | TPT CI | 1,2,3,3-Tetramethyl-3H-indolium | 1.8 |
| | 25 ppm | 0.025% | | | 1.0% | Iodide 0.3% | |
| Example 29 | HIO₃ | HFSA | 8 | MSA 1.0% | TPT CI | 3-Phenylpyrazole 0.3% | 1.8 |
| | 25 ppm | 0.025% | | | 1.0% | | |
| Example 30 | HIO₃ | HFSA | 8 | MSA 1.0% | TPT CI | Benzydamine Hydrochloride 0.3% | 1.8 |
| | 25 ppm | 0.025% | | | 1.0% | | |
| Example 31 | HIO₃ | HFSA | 49 | MSA 1.0% | TPT CI | 5-Methylbenzimidazole 0.3% | 1.8 |
| | 50 ppm | 0.20% | | | 1.0% | | |
| Example 32 | HIO₃ | HFSA | 49 | MSA 1.0% | TPT CI | 2,6-Dimethylbenzothiazole 0.3% | 1.8 |
| | 50 ppm | 0.20% | | | 1.0% | | |
| Example 33 | HIO₃ | HFSA | 49 | MSA 1.0% | TPT CI | Benzotriazole (BTA) 0.3% | 1.8 |
| | 50 ppm | 0.20% | | | 1.0% | | |
| Example 34 | HIO₃ | HFSA | 49 | MSA 1.0% | TPT CI | 1H-1,2,3-Triazolo[4.5-b]pyridine | 1.8 |
| | 50 ppm | 0.20% | | | 1.0% | 0.3% | |
| Example 35 | HIO₃ | HFSA | 49 | MSA 1.0% | TPT CI | 1-Methyl-1H-benzotriazole 0.3% | 1.8 |
| | 50 ppm | 0.20% | | | 1.0% | | |
| Example 36 | HIO₃ | HFSA | 49 | MSA 1.0% | TPT CI | Indazole 0.3% | 1.8 |
| | 50 ppm | 0.20% | | | 1.0% | | |
| Example 37 | HIO₃ | HFSA | 49 | MSA 1.0% | TPT CI | Oxindole 0.3% | 1.8 |
| | 50 ppm | 0.20% | | | 1.0% | | |
| Example 38 | HIO₃ | HFSA | 49 | MSA 1.0% | TPT CI | 4-Fluoroindazole 0.3% | 1.8 |
| | 50 ppm | 0.20% | | | 1.0% | | |
| Example 39 | HIO₃ | HFSA | 49 | MSA 1.0% | TPT CI | 5-Nitroindazole 0.3% | 1.8 |
| | 50 ppm | 0.20% | | | 1.0% | | |
| Example 40 | HIO₃ | HFSA | 49 | MSA 1.0% | TPT CI | Indazole-3-carboxylic Acid 0.3% | 1.8 |
| | 50 ppm | 0.20% | | | 1.0% | | |
| Example 41 | HIO₃ | HFSA | 49 | MSA 1.0% | TPT CI | 1,2,3,3-Tetramethyl-3H-indolium | 1.8 |
| | 50 ppm | 0.20% | | | 1.0% | Iodide 0.3% | |
| Example 42 | HIO₃ | HFSA | 49 | MSA 1.0% | TPT CI | 3-Phenylpyrazole 0.3% | 1.8 |
| | 50 ppm | 0.20% | | | 1.0% | | |
| Example 43 | HIO₃ | HFSA | 49 | MSA 1.0% | TPT CI | Benzydamine Hydrochloride 0.3% | 1.8 |
| | 50 ppm | 0.20% | | | 1.0% | | |

TABLE 8

| | ER | | | | |
|---|---|---|---|---|---|
| | TiN | | TEOS | W | Mo |
| | 2 min | | 5 min | 5 min | 5 min |
| Example 18 | 5.0 | nm/min | <1.0 nm/min | <1.0 nm/min | <1.0 nm/min |
| Example 19 | 6.5 | nm/min | <1.0 nm/min | <1.0 nm/min | <1.0 nm/min |
| Example 20 | 7.1 | nm/min | <1.0 nm/min | <1.0 nm/min | <1.0 nm/min |
| Example 21 | 6.4 | nm/min | <1.0 nm/min | <1.0 nm/min | <1.0 nm/min |
| Example 22 | 6.0 | nm/min | <1.0 nm/min | <1.0 nm/min | <1.0 nm/min |
| Example 23 | 5.0 | nm/min | <1.0 nm/min | <1.0 nm/min | <1.0 nm/min |
| Example 24 | 6.7 | nm/min | <1.0 nm/min | <1.0 nm/min | <1.0 nm/min |
| Example 25 | 5.2 | nm/min | <1.0 nm/min | <1.0 nm/min | <1.0 nm/min |
| Example 26 | 6.8 | nm/min | <1.0 nm/min | <1.0 nm/min | <1.0 nm/min |
| Example 27 | 4.7 | nm/min | <1.0 nm/min | <1.0 nm/min | <1.0 nm/min |
| Example 28 | 13.2 | nm/min | <1.0 nm/min | <1.0 nm/min | <1.0 nm/min |
| Example 29 | 5.6 | nm/min | <1.0 nm/min | <1.0 nm/min | <1.0 nm/min |
| Example 30 | 5.6 | nm/min | <1.0 nm/min | <1.0 nm/min | <1.0 nm/min |
| Example 31 | 5.6 | nm/min | <1.0 nm/min | <1.0 nm/min | <1.0 nm/min |
| Example 32 | 6.3 | nm/min | <1.0 nm/min | <1.0 nm/min | <1.0 nm/min |
| Example 33 | 8.0 | nm/min | <1.0 nm/min | <1.0 nm/min | <1.0 nm/min |
| Example 34 | 7.2 | nm/min | <1.0 nm/min | <1.0 nm/min | <1.0 nm/min |
| Example 35 | 6.7 | nm/min | <1.0 nm/min | <1.0 nm/min | <1.0 nm/min |
| Example 36 | 5.4 | nm/min | <1.0 nm/min | <1.0 nm/min | <1.0 nm/min |
| Example 37 | 7.0 | nm/min | <1.0 nm/min | <1.0 nm/min | <1.0 nm/min |
| Example 38 | 5.6 | nm/min | <1.0 nm/min | <1.0 nm/min | <1.0 nm/min |
| Example 39 | 7.2 | nm/min | <1.0 nm/min | <1.0 nm/min | <1.0 nm/min |
| Example 40 | 5.3 | nm/min | <1.0 nm/min | <1.0 nm/min | <1.0 nm/min |
| Example 41 | 13.6 | nm/min | <1.0 nm/min | <1.0 nm/min | <1.0 nm/min |
| Example 42 | 6.3 | nm/min | <1.0 nm/min | <1.0 nm/min | <1.0 nm/min |
| Example 43 | 6.0 | nm/min | <1.0 nm/min | <1.0 nm/min | <1.0 nm/min |

From the above, it has been confirmed at least that the processing solutions according to Examples can efficiently remove a protective film containing a titanium atom and is excellent in suppressing damage to a pattern. The processing solutions can be suitably used for a method for processing a substrate and a method for manufacturing a semiconductor substrate.

The present application claims priority to U.S. Provisional Application No. 63/581,858, filed with the United States Patent and Trademark Office on Sep. 11, 2023, the contents of which are incorporated herein by reference.

### EXPLANATION OF REFERENCE SIGNS

10: Substrate
20: Metal wiring layer
30: Etching stop layer
40: Interlayer insulating film
50: Hard mask layer
60: Etching residue
100: Semiconductor element (semiconductor substrate)

1. A processing solution, comprising:
an oxidizing agent (A), and
hexafluorosilicic acid (B),
wherein a molar ratio of a Si atom of the hexafluorosilicic acid (B) to the content of the oxidizing agent (A) is from 8 to 1900.

2. The processing solution according to claim 1, further comprising:
water as a solvent.

3. The processing solution according to claim 2,
wherein a pH value of the processing solution is 3.5 or less.

4. The processing solution according to claim 1,
wherein the oxidizing agent comprises at least one selected from the group consisting of iodic acid, and periodic acid.

5. The processing solution according to claim 1,
wherein the oxidizing agent comprises iodic acid.

6. The processing solution according to claim 1,
wherein a content of the oxidizing agent is from 1 to 600 ppm by mass.

7. The processing solution according to claim 1, further comprising:
an anticorrosive agent.

8. The processing solution according to claim 7,
wherein the anticorrosive agent includes two or more kinds of anticorrosive agent.

9. The processing solution according to claim 7,
wherein the anticorrosive agent comprises at least one selected from the group consisting of: an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, a phenanthroline ring-containing compound, a benzothioazole ring-containing compound, an oxindole, and tetraalkyl indolium iodide.

10. The processing solution according to claim 1,
wherein the processing solution is for a substrate that comprises a protective film containing a titanium atom, and an insulating layer containing a silicon atom.

11. The processing solution according to claim 10,
wherein the substrate further comprises a metal layer containing a metal atom other than a titanium atom and a silicon atom.

12. A method for processing a substrate, comprising:
etching a substrate comprising a protective film containing a titanium atom, and a metal layer containing a silicon atom; and
processing the etched substrate using the processing solution according to claim 1.

13. A method for manufacturing a semiconductor substrate, comprising:
etching a substrate comprising a protective film containing a titanium atom, and a metal layer containing a silicon atom; and
processing the etched substrate using the processing solution according to claim 1.
